(19) United States
(12) Patent Application Publication
(10) Pub. No.: US 2024/0234642 A1
(43) Pub. Date: Jul. 11, 2024

(54) SIDEWALL ARRANGEMENTS FOR LIGHT-EMITTING DIODE DEVICES AND RELATED METHODS

(71) Applicant: CreeLED, Inc., Durham, NC (US)

(72) Inventors: Tucker McFarlane, Cary, NC (US); Derek Miller, Columbus, OH (US); Aaron Francis, Apex, NC (US); Peter Scott Andrews, Durham, NC (US); Colin Blakely, Raleigh, NC (US)

(21) Appl. No.: 18/093,373

(22) Filed: Jan. 5, 2023

(51) Int. Cl. H01L 33/46; H01L 33/58

(52) U.S. Cl. CPC H01L 33/46; H01L 33/58; H01L 25/0753

(57) ABSTRACT

Solid-state lighting devices, and more particularly sidewall arrangements for light-emitting devices such as light-emitting diodes (LEDs) are disclosed. LED devices may include light-altering materials that are provided around peripheral sidewalls of LED chips without the need for a supporting submount or lead frame. The side layer around the peripheral sidewall of the LED chip can include an inner layer and an outer layer, each with different light altering properties. For example, the inner layer can be reflective so as to improve the light output and/or efficiency of the LED chip, while the outer layer can be absorptive so as to avoid interaction and/or crosstalk with neighboring LED chips. By having a reflective inner layer, and an absorptive outer layer, light output, sharpness, and contrast can be improved.

### FIELD OF THE DISCLOSURE

The present disclosure relates to solid-state lighting devices, and more particularly to sidewall arrangements for light-emitting devices such as light-emitting diodes (LEDs) and related methods.

### BACKGROUND

Solid-state lighting devices such as light-emitting diodes (LEDs) are increasingly used in both consumer and commercial applications. Advancements in LED technology have resulted in highly efficient and mechanically robust light sources with a long service life. Accordingly, modern LEDs have enabled a variety of new display applications and are being increasingly utilized for general illumination and automotive applications, often replacing incandescent and fluorescent light sources.

LEDs are solid-state devices that convert electrical energy to light and generally include one or more active layers of semiconductor material (or an active region) arranged between oppositely doped n-type and p-type layers. When a bias is applied across the doped layers, holes and electrons are injected into the one or more active layers where they recombine to generate emissions such as visible light or ultraviolet emissions. An LED chip typically includes an active region that may be fabricated, for example, from silicon carbide, gallium nitride, gallium phosphide, aluminum nitride, gallium arsenide-based materials, and/or from organic semiconductor materials. Photons generated by the active region are initiated in all directions.

Typically, it is desirable to operate LEDs at the highest light emission efficiency possible, which can be measured by the emission intensity in relation to the output power (e.g., in lumens per watt). A practical goal to enhance emission efficiency is to maximize extraction of light emitted by the active region in the direction of the desired transmission of light. Light extraction and external quantum efficiency of an LED can be limited by a number of factors, including internal reflection. According to the well-understood implications of Snell's law, photons reaching the surface (interface) between an LED surface and the surrounding environment are either refracted or internally reflected. If photons are internally reflected in a repeated manner, then such photons eventually are absorbed and never provide visible light that exits an LED.

LED packages, modules, and fixtures have been developed that may include multiple LED emitters that are arranged in close proximity to one another. In such applications, the LED emitters can be provided such that emissions corresponding to individual LED emitters are combined to produce desired light emissions. The emissions corresponding to individual LED emitters can be selectively generated in order to provide similar or different emission characteristics. There can be challenges in producing high quality light with desired emission characteristics when different LED emitters are provided in close proximity to one another. Additionally, conventional packaging of LED emitters may further provide spacing limitations between individual LED emitters.

The art continues to seek improved LEDs and solid-state lighting devices having desirable illumination characteristics capable of overcoming challenges associated with conventional lighting devices.

### SUMMARY

The present disclosure relates to solid-state lighting devices, and more particularly to sidewall arrangements for light-emitting devices such as light-emitting diodes (LEDs) and related methods. LED devices may include light-altering sidewall arrangements around peripheral sidewalls of LED chips without the need for a supporting submount or lead frame. The side layer around the peripheral sidewall of the LED chip can include an inner layer and an outer layer, each with different light altering properties. For example, the inner layer can be reflective so as to improve the light output and/or efficiency of the LED chip, while the outer layer can be absorptive so as to avoid interaction and/or crosstalk with neighboring LED chips. By having a reflective inner layer, and an absorptive outer layer, light output, sharpness, and contrast can be improved. Accordingly, such LED devices may be well suited for use in applications where LED devices form closely-spaced LED arrays. Fabrication techniques are disclosed that include laminating a plurality of preformed sheets of light-altering material on one or more surfaces of the LED chip.

In one aspect, an LED device includes an LED chip comprising a top face, and a bottom face. The LED device can also include a cover structure over a top face of the LED chip. The LED device can also include a side layer that bounds at least the top face and the bottom face of the LED chip, wherein the side layer comprises an inner layer comprising a first light-altering material with a first light-altering property and an outer layer comprising a second light-altering material with a second light-altering property.

In an embodiment, each of the inner layer and the outer layer of the side layer have thicknesses that are between 15 microns (μm) and 100 μm.

In another embodiment, the thicknesses of the inner layer and outer layer can be different from each other.

In an embodiment, the thicknesses of the inner layer and outer layer of the side layer are selected based on a predetermined light-altering effect.

In an embodiment, the first light-altering property of the inner layer is reflective and the second light-altering property of the outer layer is absorptive.

In another embodiment, the first light-altering property of the inner layer is reflective a first wavelength range and not reflective to a second wavelength range.

In another embodiment, the second light-altering property of the outer layer is absorptive to a first wavelength range and not absorptive to a second wavelength range.

In an embodiment, the LED device comprises a plurality of LED chips disposed on a surface, wherein each LED chip of the plurality of LED chips comprise respective side layers.

In an embodiment, the side layer also covers at least a portion of a side of the cover structure.

In an embodiment, the inner layer can be formed from at least one of silicone material or epoxy material.

In an embodiment, the outer layer of the side layer is formed from at least one of silicone material or epoxy material.

In an embodiment, the cover structure comprises one or more of a lens structure or a layer comprising a lumiphoric material.

In an embodiment, the lens structure comprises the lumiphoric material.

In an embodiment, the cover structure covers a top surface of the side layer.

In an embodiment, the cover structure has a lateral dimension larger than the LED chip, and the side layer bounds both the LED chip and the cover structure.

In an embodiment, the cover structure has a lateral dimension smaller than the LED chip, and the side layer bounds both the LED chip and the cover structure.

In an embodiment, a top and bottom of the side layer is coplanar with the top face of the LED chip and the bottom face of the LED chip, respectively.

In an embodiment, a top and bottom of the side layer is coplanar with a top surface of the cover structure and the bottom face of the LED chip, respectively.

In an embodiment, the side layer covers the top face of the LED chip.

In an embodiment, the side layer covers a top face of the cover structure.

In another aspect a method can include providing an LED chip. The method can also include providing a cover structure over a top surface of the LED chip, the cover structure comprising one or more of a lens layer or a layer comprising a lumiphoric material. The method can also include layering a first layer comprising a material with a reflective light-altering property over a top structure and a side of the LED chip. The method can also include layering a second layer comprising a material with an absorptive light-altering property over the first layer. The method can include removing the first layer and the second layer at least from the top of the cover structure, wherein the first layer and the second layer form a side layer bounding at least the top surface and a bottom surface of the LED chip.

In another aspect, a method can include providing a LED chip. The method can also include providing a cover structure over a top surface of the LED chip, the cover structure comprising one or more of a lens layer or a layer comprising a lumiphoric material. The method can also include layering a first layer comprising a material with a reflective light-altering property over a top surface of the cover structure and a side of the LED chip. The method can also include removing the first layer at least from the top of the cover structure. The method can also include layering a second layer comprising a material with an absorptive light-altering property over a top of the cover structure and the first layer on the side of the LED chip. The method can also include removing the second layer at least from the top of the cover structure, wherein the first layer and the second layer form a side layer bounding at least the top surface and a bottom surface of the LED chip.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1A is a cross-sectional view of a light-emitting diode (LED) device according to aspects disclosed herein.

FIGS. 1B and 1C are top views of the LED device of FIG. 1A.

FIG. 2 is a cross-sectional view of an LED device with a wider cover structure than LED chip according to aspects disclosed herein.

FIG. 3 is a cross-sectional view of an LED device with a wider LED chip than cover structure according to aspects disclosed herein.

FIG. 4 is a cross-sectional view of an LED device similar to the LED device of FIG. 1A with a cover structure with a different configuration of layers according to aspects disclosed herein.

FIG. 5 is a cross-sectional view of an LED device with the side layer bounding a cover structure that includes a lens with embedded conversion material according to aspects disclosed herein.

FIG. 6 is a cross-sectional view of an LED device with the side layer bounding a cover structure that includes just a lens according to aspects disclosed herein.

FIGS. 7-10 depict cross-sectional views of LED devices similar to FIG. 1A, where the cover structures cover a top of the side layer according to aspects disclosed herein.

FIGS. 11-14 depict cross-sectional views of LED devices with different dome-shaped cover structures that are not bounded by the side layer according to aspects disclosed herein.

FIGS. 15-18 depict cross-sectional views of LED devices with different dome-shaped cover structures that cover a top of the side layer according to aspects disclosed herein.

FIG. 19 is a flowchart of a method for fabricating an LED device according to aspects disclosed herein.

FIG. 20 is a flowchart of another method for fabricating an LED device according to aspects disclosed herein.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

The present disclosure relates to solid-state lighting devices, and more particularly to sidewall arrangements for light-emitting devices such as light-emitting diodes (LEDs) and related methods. LED devices may include light-altering materials that are provided around peripheral sidewalls of LED chips without the need for a supporting submount or lead frame. The side layer around the peripheral sidewall of the LED chip can include an inner layer and an outer layer, each with different light altering properties. For example, the inner layer can be reflective so as to improve the light output and/or efficiency of the LED chip, while the outer layer can be absorptive so as to avoid interaction and/or crosstalk with neighboring LED chips. By having a reflective inner layer, and an absorptive outer layer, light output, sharpness, and contrast can be improved. Accordingly, such LED devices may be well suited for use in applications where LED devices form closely-spaced LED arrays. Fabrication techniques are disclosed that include laminating a plurality of preformed sheets of light-altering material on one or more surfaces of the LED chip.

An LED chip typically comprises an active LED structure or region that can have many different semiconductor layers arranged in different ways. The fabrication and operation of LEDs and their active structures are generally known in the art and are only briefly discussed herein. The layers of the active LED structure can be fabricated using known processes with a suitable process being fabrication using metal organic chemical vapor deposition. The layers of the active LED structure can comprise many different layers and generally comprise an active layer sandwiched between n-type and p-type oppositely doped epitaxial layers, all of which are formed successively on a growth substrate. It is understood that additional layers and elements can also be included in the active LED structure, including, but not limited to, buffer layers, nucleation layers, super lattice structures, un-doped layers, cladding layers, contact layers, and current-spreading layers and light extraction layers and elements. The active layer can comprise a single quantum well, a multiple quantum well, a double heterostructure, or super lattice structures.

The active LED structure can be fabricated from different material systems, with some material systems being Group III nitride-based material systems. Group III nitrides refer to those semiconductor compounds formed between nitrogen (N) and the elements in Group III of the periodic table, usually aluminum (Al), gallium (Ga), and indium (In). Gallium nitride (GaN) is a common binary compound. Group III nitrides also refer to ternary and quaternary compounds such as aluminum gallium nitride (AlGaN), indium gallium nitride (InGaN), and aluminum indium gallium nitride (AlInGaN). For Group III nitrides, silicon (Si) is a common n-type dopant and magnesium (Mg) is a common p-type dopant. Accordingly, the active layer, n-type layer, and p-type layer may include one or more layers of GaN, AlGaN, InGaN, and AlInGaN that are either undoped or doped with Si or Mg for a material system based on Group III nitrides. Other material systems include silicon carbide (SiC), organic semiconductor materials, and other Group III-V systems such as gallium phosphide (GaP), gallium arsenide (GaAs), and related compounds.

The active LED structure may be grown on a growth substrate that can include many materials, such as sapphire, SiC, aluminum nitride (AlN), and GaN, with a suitable substrate being a 4H polytype of SiC, although other SiC polytypes can also be used including 3C, 6H, and 15R polytypes. SiC has certain advantages, such as a closer crystal lattice match to Group III nitrides than other substrates and results in Group III nitride films of high quality. SiC also has a very high thermal conductivity so that the total output power of Group III nitride devices on SiC is not limited by the thermal dissipation of the substrate. Sapphire is another common substrate for Group III nitrides and also has certain advantages, including being lower cost, having established manufacturing processes, and having good light-transmissive optical properties.

Different embodiments of the active LED structure can emit different wavelengths of light depending on the composition of the active layer and n-type and p-type layers. In some embodiments, the active LED structure emits blue light with a peak wavelength range of approximately 430 nanometers (nm) to 480 nm. In other embodiments, the active LED structure emits green light with a peak wavelength range of 500 nm to 570 nm. In other embodiments, the active LED structure emits red light with a peak wavelength range of 600 nm to 650 nm.

An LED chip can also be covered with one or more lumiphoric materials (also referred to herein as lumiphors), such as phosphors, such that at least some of the light from the LED chip is absorbed by the one or more lumiphors and is converted to one or more different wavelength spectra according to the characteristic emission from the one or more lumiphors. In this regard, at least one lumiphor receiving at least a portion of the light generated by the LED source may re-emit light having different peak wavelength than the LED source. An LED source and one or more lumiphoric materials may be selected such that their combined output results in light with one or more desired characteristics such as color, color point, intensity, etc. In certain embodiments, aggregate emissions of LED chips, optionally in combination with one or more lumiphoric materials, may be arranged to provide cool white, neutral white, or warm white light, such as within a color temperature range of from 2500K to 10,000K. In certain embodiments, lumiphoric materials having cyan, green, amber, yellow, orange, and/or red peak wavelengths may be used. In some embodiments, the combination of the LED chip and the one or more lumiphors (e.g., phosphors) emits a generally white combination of light. The one or more phosphors may include yellow (e.g., YAG:Ce), green (e.g., LuAg:Ce), and red (e.g., Ca_{1-x-y}SrₓEu_{y}AlSiN₃) emitting phosphors, and combinations thereof.

Lumiphoric materials as described herein may be or include one or more of a phosphor, a scintillator, a lumiphoric ink, a quantum dot material, a day glow tape, and the like. Lumiphoric materials may be provided by any suitable means, for example, direct coating on one or more surfaces of an LED, dispersal in an encapsulant material configured to cover one or more LEDs, and/or coating on one or more optical or support elements (e.g., by powder coating, inkjet printing, or the like). In certain embodiments, lumiphoric materials may be downconverting or upconverting, and combinations of both downconverting and upconverting materials may be provided. In certain embodiments, multiple different (e.g., compositionally different) lumiphoric materials arranged to produce different peak wavelengths may be arranged to receive emissions from one or more LED chips. One or more lumiphoric materials may be provided on one or more portions of an LED chip in various configurations. In certain embodiments, one or more surfaces of LED chips may be conformally coated with one or more lumiphoric materials, while other surfaces of such LED chips may be devoid of lumiphoric material. In certain embodiments, a top surface of an LED chip may include lumiphoric material, while one or more side surfaces of an LED chip may be devoid of lumiphoric material. In certain embodiments, all or substantially all outer surfaces of an LED chip (e.g., other than contact-defining or mounting surfaces) are coated or otherwise covered with one or more lumiphoric materials. In certain embodiments, one or more lumiphoric materials may be arranged on or over one or more surfaces of an LED chip in a substantially uniform manner. In other embodiments, one or more lumiphoric materials may be arranged on or over one or more surfaces of an LED chip in a manner that is non-uniform with respect to one or more of material composition, concentration, and thickness. In certain embodiments, the loading percentage of one or more lumiphoric materials may be varied on or among one or more outer surfaces of an LED chip. In certain embodiments, one or more lumiphoric materials may be patterned on portions of one or more surfaces of an LED chip to include one or more stripes, dots, curves, or polygonal shapes. In certain embodiments, multiple lumiphoric materials may be arranged in different discrete regions or discrete layers on or over an LED chip.

In certain embodiments, one or more lumiphoric materials may be provided as at least a portion of a wavelength conversion element. Wavelength conversion elements may include a support element, such as a superstrate, and one or more lumiphoric materials that are provided by any suitable means, such as by coating a surface of the superstrate or by incorporating within the superstrate. The term “superstrate” as used herein refers to an element placed on or over an LED chip that may include a lumiphoric material. The term “superstrate” is used herein, in part, to avoid confusion with other substrates that may be part of the semiconductor light-emitting device, such as a growth or carrier substrate of the LED chip or a submount of an LED package. The term “superstrate” is not intended to limit the orientation, location, and/or composition of the structure it describes. In some embodiments, the superstrate may be composed of a transparent material, a semi-transparent material, or a light-transmissive material, such as sapphire, SiC, silicone, and/or glass (e.g., borosilicate and/or fused quartz). Superstrates may be patterned to enhance light extraction as described in commonly-assigned U.S. Patent Application Publication No. 2019/0326484 entitled “Semiconductor Light Emitting Devices Including Superstrates with Patterned Surfaces” which is hereby incorporated by reference herein. Superstrates may also be configured as described in commonly-assigned U.S. Patent Application Publication No. 2018/0033924, also incorporated by reference herein. Superstrates may be formed from a bulk substrate which is optionally patterned and then singulated. In certain embodiments, the patterning of a superstrate may be performed by an etching process (e.g., wet or dry etching). In certain embodiments, the patterning of a superstrate may be performed by otherwise altering the surface, such as by a laser or saw. In certain embodiments, the superstrate may be thinned before or after the patterning process is performed. In certain embodiments, superstrates may comprise a generally planar upper surface that corresponds to a light emission area of the LED package.

One or more lumiphoric materials may be arranged on the superstrate by, for example, spraying and/or otherwise coating the superstrate with the lumiphoric materials. Wavelength conversion elements may be attached to one or more LED chips using, for example, a layer of transparent adhesive. In certain embodiments, the layer of the transparent adhesive may include silicone with a refractive index in a range of about 1.3 to about 1.6 that is less than a refractive index of the LED chip on which the wavelength conversion element is placed. In other embodiments, wavelength conversion elements may comprise alternative configurations, such as phosphor-in-glass or ceramic phosphor plate arrangements. Phosphor-in-glass or ceramic phosphor plate arrangements may be formed by mixing phosphor particles with glass frit or ceramic materials, pressing the mixture into planar shapes, and firing or sintering the mixture to form a hardened structure that can be cut or separated into individual wavelength conversion elements.

Light emitted by the active layer or region of an LED chip is initiated in all directions. For directional applications, internal mirrors or external reflective surfaces may be employed to redirect as much light as possible toward a desired emission direction. Internal mirrors may include single or multiple layers. Some multi-layer mirrors include a metal reflective layer and a dielectric reflective layer, wherein the dielectric reflective layer is arranged between the metal reflective layer and a plurality of semiconductor layers. A passivation layer is arranged between the metal reflective layer and first and second electrical contacts, wherein the first electrical contact is arranged in conductive electrical communication with a first semiconductor layer, and the second electrical contact is arranged in conductive electrical communication with a second semiconductor layer. For single or multi-layer mirrors including surfaces exhibiting less than 100% reflectivity, some light may be absorbed by the mirror. Additionally, light that is redirected through the active LED structure may be absorbed by other layers or elements within the LED chip.

As used herein, a layer or region of a light-emitting device may be considered to be “transparent” when at least 80% of emitted radiation that impinges on the layer or region emerges through the layer or region. Moreover, as used herein, a layer or region of an LED is considered to be “reflective” or embody a “mirror” or a “reflector” when at least 80% of the emitted radiation that impinges on the layer or region is reflected. In some embodiments, the emitted radiation comprises visible light such as blue and/or green LEDs with or without lumiphoric materials. In other embodiments, the emitted radiation may comprise nonvisible light. For example, in the context of GaN-based blue and/or green LEDs, silver (Ag) may be considered a reflective material (e.g., at least 80% reflective). In the case of ultraviolet (UV) LEDs, appropriate materials may be selected to provide a desired, and in some embodiments high, reflectivity and/or a desired, and in some embodiments low, absorption. In certain embodiments, a “light-transmissive” material may be configured to transmit at least 50% of emitted radiation of a desired wavelength.

The present disclosure can be useful for LED chips having a variety of geometries, such as vertical geometry or lateral geometry. A vertical geometry LED chip typically includes anode and cathode connections on opposing sides or faces of the LED chip. A lateral geometry LED chip typically includes both anode and cathode connections on the same side of the LED chip that is opposite a substrate, such as a growth substrate. In certain embodiments, a lateral geometry LED chip may be arranged for flip-chip mounting on another surface

Aspects as disclosed herein may be useful for LED modules, systems or fixtures that include closely-spaced LED emitters or devices that are capable of providing overall combined emissions as well as a number of changeable, selectable, or tunable emission characteristics that are provided by separately controlling the LED devices. In this manner, LED devices are arranged as close to one another as possible so they may appear as a single emission area when all are electrically activated, and when different emissions characteristics are desired, certain ones or groups of closely-spaced LED devices may be separately electrically activated or deactivated. In such applications, size and spacing limitations can make it impractical to use separately packaged LEDs. Conventional LED packages typically include an LED chip that is mounted on a larger submount and an encapsulant that encloses the LED chip on the submount, thereby providing the LED package with an increased footprint relative to the LED chip. Additionally, conventional LED packages may also include multiple LED chips that are arranged on a common substrate (e.g., a ceramic panel) or a leadframe package. However, this also contributes to an increased package footprint in order to accommodate the common substrate or leadframe. This increased footprint can be undesirable for manufacturers that want to build pixelated lighting systems, such as those used for adaptive automotive headlights or display applications.

According to aspects disclosed herein, LED devices are provided with reduced footprints that allow for the assembly of arrays of closely-spaced LED devices on common supports, such as printed circuit boards (PCBs). LED devices as disclosed herein may be fabricated to be devoid of conventional submounts and leadframes that contribute to increased footprints. In certain aspects, an LED device that is capable of being attached to external electrical connections, such as those provided on a PCB, without the use of a conventional submount and leadframe may be referred to as a chip scale package (CSP). In this regard, a CSP may include one or more elements, such as lumiphoric materials, encapsulants, light-altering materials, lens, and electrical contacts, among others, which are provided with one or more LED chips without a conventional submount or leadframe. For closely-spaced applications, the LED devices (e.g., CSPs) may also be configured to avoid interaction or cross-talk that may be caused by emissions that bleed over from adjacent LED devices. In this regard, LED devices as disclosed herein may be configured with a footprint that is close to a footprint of the LED chip within the LED device while also providing an amount of light-altering material around peripheral edges of the LED chip to reduce cross-talk.

As used herein, light-altering materials may include many different materials including light-reflective materials that reflect or redirect light, light-absorbing materials that absorb light, and materials that act as a thixotropic agent. As used herein, the term “light-reflective” refers to materials or particles that reflect, refract, or otherwise redirect light. For light-reflective materials, the light-altering material may include at least one of fused silica, fumed silica, titanium dioxide (TiO₂), or metal particles suspended in a binder, such as silicone or epoxy. For light-absorbing materials, the light-altering material may include at least one of carbon, silicon, or metal particles suspended in a binder, such as silicone or epoxy. The light-reflective materials and the light-absorbing materials may comprise nanoparticles. In certain embodiments, the light-altering material may comprise a generally white color to reflect and redirect light. In other embodiments, the light-altering material may comprise a generally opaque or black color for absorbing light and increasing contrast.

In certain embodiments, the light-altering material includes both light-reflective material and light-absorbing material suspended in a binder. A weight ratio of the light-reflective material to the binder may comprise a range of about 1:1 to about 2:1. A weight ratio of the light-absorbing material to the binder may comprise a range of about 1:400 to about 1:10. In certain embodiments, a total weight of the light-altering material includes any combination of the binder, the light-reflective material, and the light-absorbing material. In some embodiments, the binder may comprise a weight percent that is in a range of about 10% to about 90% of the total weight of the light-altering material. The light-reflective material may comprise a weight percent that is in a range of about 10% to about 90% of the total weight of the light-altering material. The light-absorbing material may comprise a weight percent that is in a range of about 0% to about 15% of the total weight of the light-altering material.

In further embodiments, the light-absorbing material may comprise a weight percent that is in a range of about greater than 0% to about 15% of the total weight of the light-altering material. In further embodiments, the binder may comprise a weight percent that is in a range of about 25% to about 70% of the total weight of the light-altering material. The light-reflective material may comprise a weight percent that is in a range of about 25% to about 70% of the total weight of the light-altering material. The light-absorbing material may comprise a weight percent that is in a range of about 0% to about 5% of the total weight of the light-altering material. In further embodiments, the light-absorbing material may comprise a weight percent that is in a range of about greater than 0% to about 5% of the total weight of the light-altering material.

In certain aspects, light-altering materials may be provided in a preformed sheet or layer that includes light-altering particles suspended in a binder. For example, light-altering particles may be suspended in a binder of silicone that is not fully cured to provide the preformed sheet of light-altering materials. A desired thickness or height of the preformed sheet may be provided by moving a doctor blade or the like across the sheet. The preformed sheet may then be positioned on and subsequently formed around an LED chip and/or a wavelength conversion element that is on the LED chip. For example, the preformed sheet may be laminated around the LED chip and/or wavelength conversion element and then the performed sheet may be fully cured in place. One or more portions of the preformed sheet may then be removed from a primary light-emitting face of the LED chip and/or wavelength conversion element. In this manner, light-altering materials may be formed along peripheral edges or sidewalls of the LED chip and wavelength conversion element with thicknesses not previously possible with conventional dispensing techniques typically used to form light-altering materials. Additionally, light-altering materials may be provided without needing conventional submounts or lead frames as support for conventional dispensing and/or molding techniques. In this regard, LED devices with light-altering materials may be provided with reduced footprints suitable for closely-spaced LED arrangements.

In certain applications, LED devices as disclosed herein may be well suited in closely-spaced array applications such automotive lighting, general lighting, and lighting displays. For exterior automotive lighting, multiple LED devices may be arranged under a common lens or optic to provide a single overall emission or emissions that are capable of changing between different emission characteristics. Changing emission characteristics may include toggling between high beam and low beam emissions, adaptively changing emissions, and adjusting correlated color temperatures (CCTs) that correspond with daytime and nighttime running conditions. In general lighting applications, LED devices as disclosed herein may be configured to provide modules, systems, and fixtures that are capable of providing one or more different emission colors or CCT values, such as one or more of warm white (e.g., 2700 Kelvin (K)-3000 K), neutral white (e.g., 3500 K-4500 K), and cool white (5000 K-6500 K). For horticulture lighting applications, LED devices as disclosed herein may be arranged to provide modules, systems, and fixtures that are capable of changing between different emission characteristics that target various growth conditions of different crops.

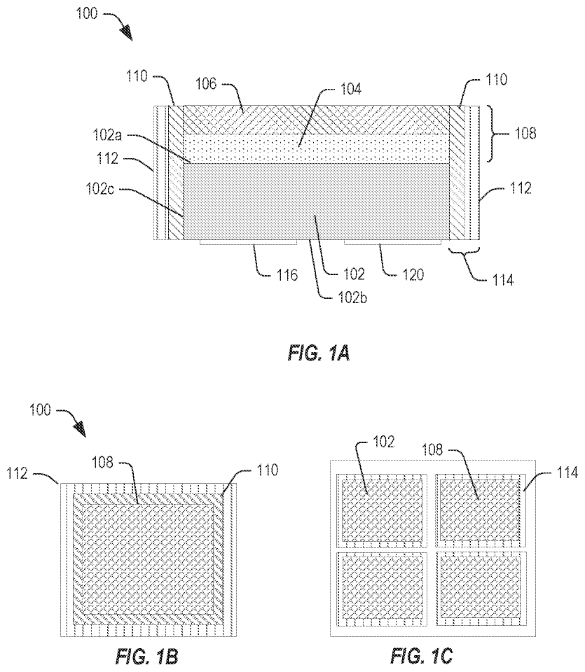

FIG. 1A is a cross-sectional view of an LED device 100 according to aspects disclosed herein. The LED device 100 includes an LED chip 102 and the LED device 100 is devoid of a submount and/or lead frame typically found in conventional LED packages. In this regard, the LED device 100 may be referred to as a CSP. While FIG. 1A illustrates a single LED chip 102, the LED device 100 may include a plurality of LED chips 102 without deviating from the principles disclosed herein. The LED chip 102 may include a top face 102a, a bottom face 102b, and peripheral sidewalls 102c that bound the top face 102a and the bottom face 102b. By way of example, for a square or rectangular area of the top face 102a and the bottom face 102b, the LED chip 102 may comprise four peripheral sidewalls 102c. In certain embodiments, the LED device 10 may comprise a cover structure 108 that includes a lens 106 and a conversion layer 104 that comprises lumiphoric material. The lens 106 may comprise a material that is light-transmissive and/or transparent to light emitted by the LED chip 102 and light that is converted by the conversion layer 104. The lens 106 may also be textured to improve light extraction or contain materials such as phosphors or scattering particles. The conversion layer 104 may comprise any of the materials as previously described, including one or more phosphors that provide the same or different emission characteristics. In certain embodiments, the lens 106 and the conversion layer 104 may be attached to the LED chip 102 using, for example, a layer of transparent adhesive such as silicone. In certain embodiments, the conversion layer 104 is formed between the lens 106 and the LED chip 102, thereby protecting the conversion layer 104 from environmental exposure.

As further illustrated in FIG. 1A, a side layer 114 is provided around and/or on the peripheral sidewalls 102c of the LED chip 102. The side layer 114 may also be provided around and/or on peripheral side surfaces of the cover structure 108. As described above and will be described in greater detail below, the side layer 114 may be formed by a lamination process. The side layer 114 can comprise an inner layer 110 and an outer layer 112, with each of the inner layer 110 and the outer layer 112 providing different light-altering properties.

In certain embodiments, the thickness of each of the inner layer 110 and the outer layer 112 is in a range including 15 microns (μm) and 100 μm, or in a range including 15 μm and 60 μm, or in a range including 15 μm and 50 μm, or in a range including 20 μm and 50 μm. Such thicknesses may be configured differently for different dimensions of the LED chip 102 or based on different desired light-altering effects.

As illustrated in FIG. 1A, the side layer 114 may be formed in such a manner that the side layer 114 is conformal to the peripheral sidewalls 102c of the LED chip 102 and peripheral side surfaces of the conversion layer 104 and lens 106 of the cover structure 108. In this regard, the thickness of the side layer 114 may be the same for both the peripheral sidewalls 102c of the LED chip 102 and peripheral side surfaces of the cover structure 108 with a curved transition therebetween. Additionally, a top surface of the inner layer 110 and outer layer 112 may be arranged to be coplanar or substantially coplanar with a top face of the cover structure 108. In this manner, the top face of the cover structure 108 forms a primary light-emitting face of the LED device 100. The LED device 100 may further include a cathode contact 116 and an anode contact 120 that are provided on the bottom face 102b of the LED chip 102 in a flip-chip arrangement. A bottom surface of the inner layer 110 and the outer layer 112 may be coplanar with the bottom face 102b of the LED chip 102, or coplanar with bottom surfaces of the cathode contact 116 and the anode contact 120. With this arrangement, the cathode contact 116 and the anode contact 120 may be configured for direct mounting with external electrical connections, such as electrical traces of a PCB.

In one or more embodiments, the side layer 114 can also cover the top face 102a of the LED chip 102, or alternatively a top surface or face of the cover structure 108 as well. In this way the entire light output of the LED chip 102 can be altered in accordance with the light altering properties of the inner layer 110 and the outer layer 112.

In an embodiment, the inner layer 110 and the outer layer 112 that form the side layer 114 can comprise silicone or epoxy. Different light-altering materials can be embedded in the inner layer 110 and the outer layer 112 to adjust the type of light altering effect (reflective vs absorptive) or magnitude of the effect. In various embodiments, the light-altering properties can be selective to the wavelength in which the light-altering properties are effective. For example, the inner layer 110 could be reflective to a first range of wavelengths of light, while it is transparent, or more transmissive and less reflective, to a second range of wavelengths. As an example of light-altering materials that can be added to the inner layer 110 and the outer layer 112, zirconia or alumina can be added to increase reflectivity, while carbon black can be added to increase absorptivity. Chromium particles could be added as a pseudo-filter that increases the reflectivity to certain wavelengths while allowing other wavelengths to pass. Other light-altering materials are possible as well. The thicknesses of the inner layer 110 and the outer layer 112 as well as the density of the embedded light-altering materials can be adjusted based on the desired light altering effects. For example, if contrast and reduction in interference is most important, the outer layer 112 can be thick relative to the inner layer 110, and the density of the added absorptive light-altering materials to the outer layer 112 can be increased. On the other hand, if increased light output is more important, the inner layer 110 can be thick relative to the outer layer 112, and the density of the added reflective light-altering materials in the inner layer 110 can be increased.

FIG. 1B is a top view of the LED device 100 of FIG. 1A. As illustrated, the inner layer 110 and the outer layer 112 is arranged around a perimeter of the cover structure 108.

FIG. 1C is another top view of the LED device 100 of FIG. 1A, but on a device where there are a plurality of LED chips 102. The LED chips 102 can form an array, and the side layer 114 around each of the respective LED chips 102 and cover structure 108 can reduce the interference and crosstalk between the LED chips 102, and lead to increased contrast, control of light emission patterns, and increased output.

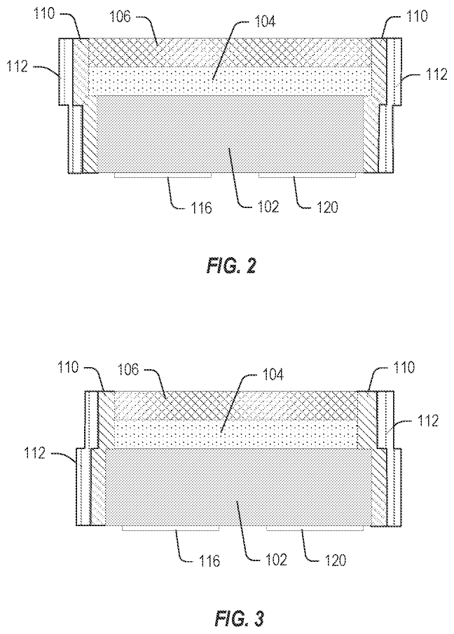

FIG. 2 illustrates a cross-sectional view of an LED device 100 with a wider cover structure than LED chip 102 according to aspects disclosed herein. The lens 106 and the conversion layer 104 can extend beyond a peripheral sidewall of the LED chip 102, and the inner layer 110 and the outer layer 112 can conform to the sidewalls of the cover structure and the LED chip 102. The arrangement of FIG. 2 may be advantageous to allow tolerances for slight lateral deviations when the cover structure is attached to the LED chip 102. A similar, but opposite embodiment is shown in FIG. 3, where the LED chip 102 is wider than the lens 106 and the conversion layer 104.

In an embodiment, as shown in FIGS. 2 and 3, the inner layer 110 and outer layer 112 can have squared corners when adjusting for the differences in widths between the LED chip 102 and the cover structure. In other embodiments however, the inner layer 110 and/or outer layer 112 can have more gradual, or curved angles.

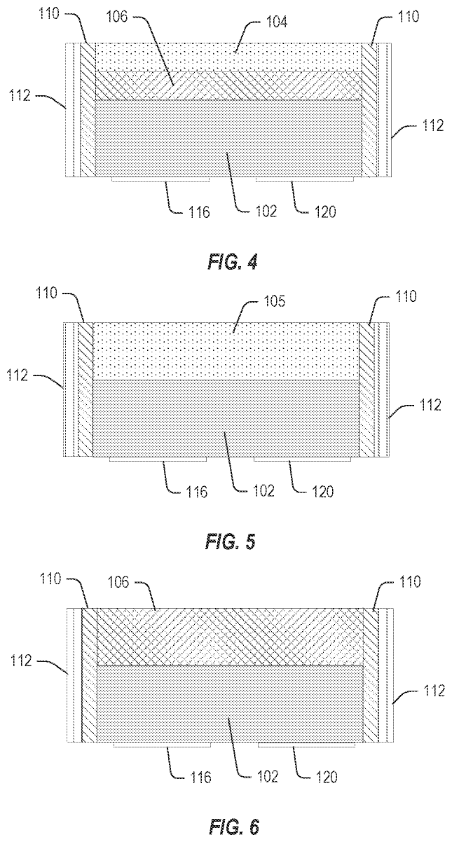

FIG. 4 is a cross-sectional view of an LED device similar to the LED device of FIG. 1A with a cover structure with a different configuration of layers according to aspects disclosed herein. FIG. 4 is different than the embodiment shown in FIG. 1A, except that instead of the conversion layer 104 being proximate to the LED chip 102, in FIG. 4, the lens 106 of the cover structure is proximate to a top surface of the LED chip 102, and the conversion layer 104 is above the lens 106.

In FIG. 5, the cover structure includes just a single layer 105 that is a lens with an embedded conversion layer, or a lens that includes lumiphoric material. In contrast, in the embodiment depicted in FIG. 6, the LED device 100 includes a cover structure comprising just a lens 106 without a conversion layer 104. In each of the various embodiments shown in FIGS. 1A and 2-6, a top of the inner layer 110 and the outer layer 112 is coplanar with a top of the cover structure, while a bottom of the inner layer 110 and outer layer 112 is coplanar with a bottom of the LED chip 102 or the cathode 116 and anode 114.

FIGS. 7-10 depict cross-sectional views of LED devices similar to FIG. 1A, where the cover structures cover a top of the side layer 114 according to aspects disclosed herein.

In the embodiment depicted in FIG. 7, the conversion layer 104 is atop a lens 106, which covers both the lens 102 and a top surface of the inner layer 110 and the outer layer 112. FIG. 8 depicts an alternate embodiment to FIG. 7 where the layers of the cover structure 108 are switched and the conversion layer 104 is proximate to the lens 102, while the lens 106 lays above the conversion layer 104.

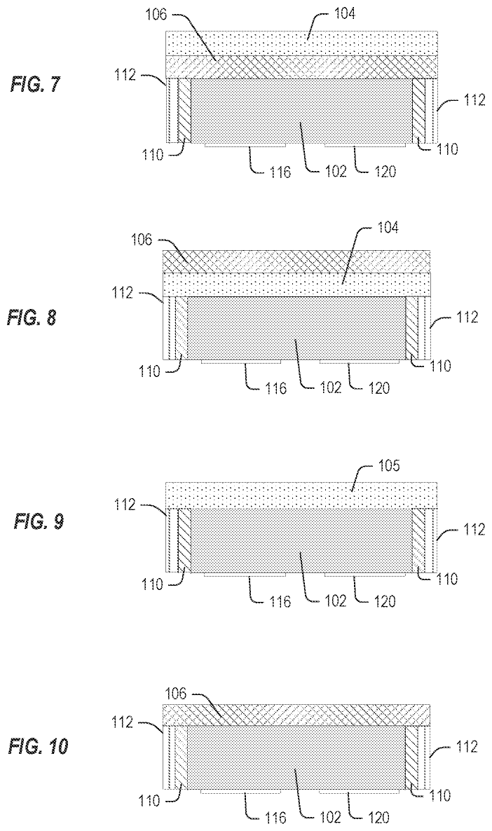

In the embodiment depicted in FIG. 9, the layer 105 that comprises a lens with an embedded lumiphoric material covers both the lens 102 and a top surface of the inner layer 110 and the outer layer 112. FIG. 10 depicts an alternate embodiment to FIG. 9 where a single lens 106 covers a top surface of the lens 102 and the top surfaces of the inner layer 110 and the outer layer 112.

FIGS. 11-14 depict cross-sectional views of LED devices with different dome-shaped cover structures that are not bounded by the side layer according to aspects disclosed herein.

In FIG. 11 a dome shaped lens layer 106 covers a conversion layer 104 that covers the LED chip 102 while not covering the inner layer 110 and the outer layer 112 of the side layer 114. The top surfaces of the inner layer 110 and the outer layer 112 are coplanar with a top surface of the conversion layer 104.

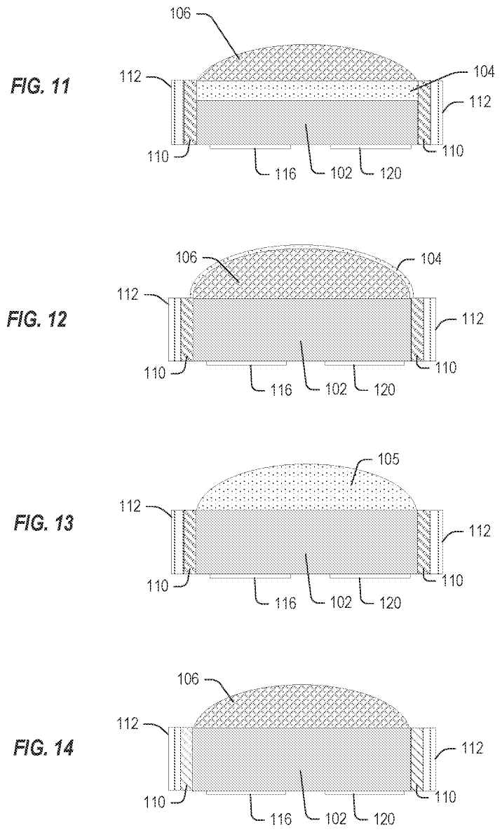

In FIG. 12, a dome shaped lens 106 covers the LED chip 102 while not covering the inner layer 110 and the outer layer 112 of the side layer 114. The top surfaces of the inner layer 110 and the outer layer 112 are coplanar with a top surface of the LED chip 102. Additionally, a conversion layer 104 is provided over a top surface of the dome shaped lens 106.

In FIG. 13, a dome shaped layer 105 that comprises a lens with an embedded lumiphoric material covers the LED chip 102, while the top surfaces of the inner layer 110 and the outer layer 112 are coplanar with a top surface of the LED chip 102.

In FIG. 14, a dome shaped lens 106 covers the LED chip 102, while the top surfaces of the inner layer 110 and the outer layer 112 are coplanar with a top surface of the LED chip 102.

FIGS. 15-18 depict cross-sectional views of LED devices with different dome-shaped cover structures that cover a top of the side layer according to aspects disclosed herein.

FIG. 15 depicts a similar LED device as shown in FIG. 11, except that in FIG. 15, the dome shaped lens 106 covers a top surface of the inner layer 110 and the outer layer 112.

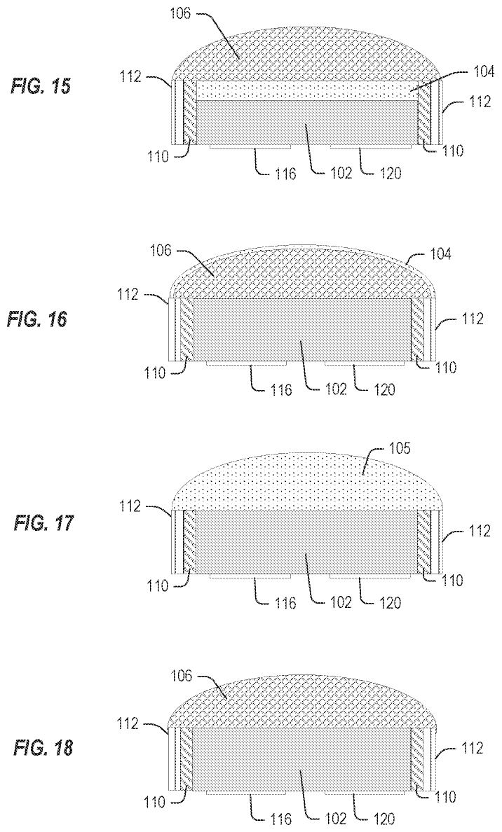

FIG. 16 depicts a similar LED device as shown in FIG. 12, except that in FIG. 16, the dome shaped lens 106 covers a top surface of the inner layer 110 and the outer layer 112, while the conversion layer 104 is provided over a top surface of the dome shaped lens 106.

FIG. 17 depicts a similar LED device as shown in FIG. 13, except that in FIG. 17, the dome shaped layer 105 that comprises a lens with an embedded lumiphoric material covers a top surface of the inner layer 110 and the outer layer 112.

FIG. 18 depicts a similar LED device as shown in FIG. 14, except that in FIG. 18, the dome shaped lens 106 covers a top surface of the inner layer 110 and the outer layer 112.

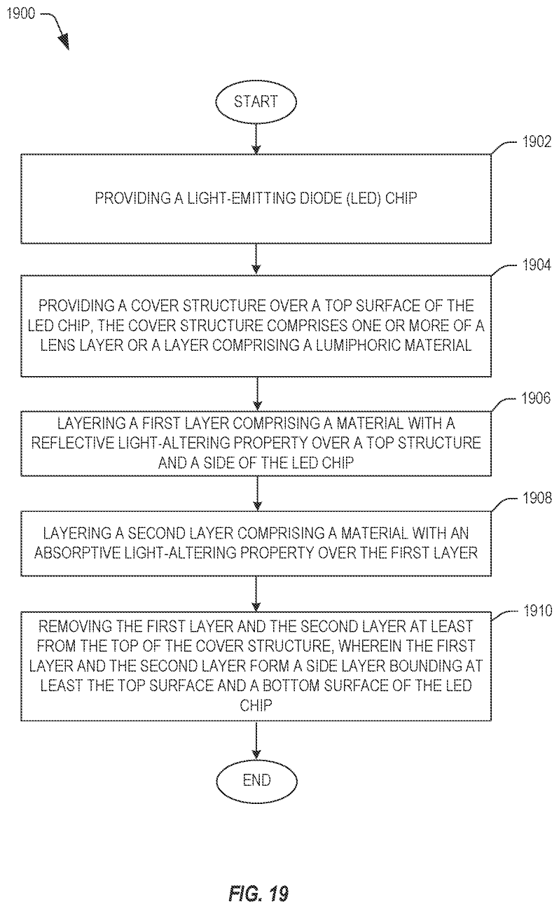

FIG. 19 is a flowchart of a method for fabricating an LED device similar to the LED devices depicted in FIGS. 1A-1C, and FIGS. 2-18 according to aspects disclosed herein. In an embodiment, the general method of fabrication covers a package design in which die are attached to tape, covered with a lens, laminated with silicone or epoxy sheets containing reflective materials and absorbing materials under vacuum, the sheets can then be removed to reveal the lens without damaging the sidewalls, and the die can then be singulated into a low footprint CSP.

The method can begin at step 1902, which includes providing a LED chip. The LED chip can be one of many LED chips formed together.

At step 1904, the method includes providing a cover structure over a top surface of the LED chip, the cover structure comprising one or more of a lens layer (e.g., lens 106) or a layer comprising a lumiphoric material. The layer comprising the lumiphoric layer can be the conversion layer 104 described above.

At step 1906, the method includes layering a first layer comprising a material with a reflective light-altering property over a top structure and a side of the LED chip. The first layer can be the inner layer 110.

At step 1908, the method includes layering a second layer comprising a material with an absorptive light-altering property over the first layer. The second layer is the outer layer 112. The first layer and the second layer can each have a thickness in a range including 15 microns (μm) and 100 μm. Additionally, the first layer and the second layer can be comprised of silicone or an epoxy. The epoxy matrix used to fabricate the layers can include fibers to reinforce the layer. During the layering process of the first layer and the second layer, the layer sheets can be placed onto a lamination tool, where they sit on pegs above a hotplate. The tool is then vacuumed out so that the sheets are pressed against the die giving the conformal shape to the sidewalls. The pegs then lower the parts onto a hotplate so that the sheets cure.

At step 1910, the method includes removing the first layer and the second layer at least from the top of the cover structure, wherein the first layer and the second layer form a side layer bounding at least the top surface and a bottom surface of the LED chip. The removal process can occur via abrasion and/or polishing, where the polishing tool is configured to just remove the sheets of material layered overt the lens.

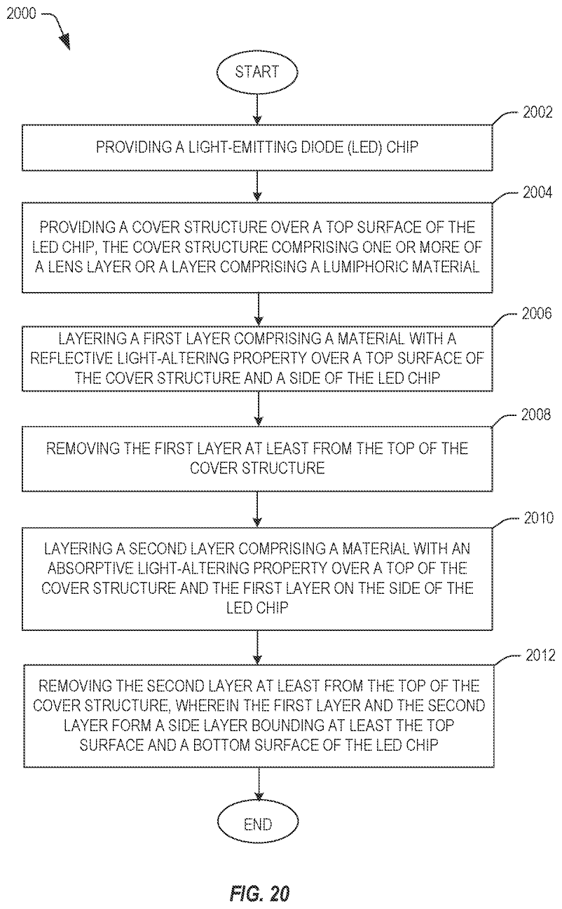

FIG. 20 is a flowchart of another method for fabricating an LED device similar to the LED devices depicted in FIGS. 1A-1C, and FIGS. 2-18 according to aspects disclosed herein

The method can begin at step 2002, which includes providing a LED chip.

At step 2004, the method includes providing a cover structure over a top surface of the LED chip, the cover structure comprising one or more of a lens layer or a layer comprising a lumiphoric material.

At step 2006, the method includes layering a first layer comprising a material with a reflective light-altering property over a top surface of the cover structure and a side of the LED chip.

At step 2008, the method includes removing the first layer at least from the top of the cover structure.

At step 2010, the method includes layering a second layer comprising a material with an absorptive light-altering property over a top of the cover structure and the first layer on the side of the LED chip.

At step 2012, the method includes removing the second layer at least from the top of the cover structure, wherein the first layer and the second layer form a side layer bounding at least the top surface and a bottom surface of the LED chip.

The steps of the methods in FIGS. 19-20 create LED devices as depicted in FIGS. 1A, and FIGS. 2-6 where the tops of the inner layer 110 and outer layer 112 are coplanar with a top of the cover structure. In embodiments as depicted in FIGS. 7-18 where the top surfaces of the inner layer 110 and outer layer 112 are coplanar with a top surface of the LED chip 102, the methods in FIGS. 19-20 can be modified by forming and removing the first layer and second layer before the lens 106 or the conversion layer 104 is attached to the top of the LED chip 102.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. A light-emitting diode (LED) device comprising:
an LED chip comprising a top face, and a bottom face;
a cover structure over the top face of the LED chip; and
a side layer that bounds at least the top face and the bottom face of the LED chip, wherein the side layer comprises an inner layer comprising a first light-altering material with a first light-altering property and an outer layer comprising a second light-altering material with a second light-altering property.

2. The LED device of claim 1, wherein each of the inner layer and the outer layer of the side layer have thicknesses that are between 15 microns (μm) and 100 μm.

3. The LED device of claim 2, where a thickness of the inner layer is different than a thickness of the outer layer.

4. The LED device of claim 2, wherein the thicknesses of the inner layer and outer layer of the side layer are selected based on a predetermined light-altering effect.

5. The LED device of claim 1, wherein the first light-altering property of the inner layer is reflective and the second light-altering property of the outer layer is absorptive.

6. The LED device of claim 5, wherein the first light-altering property of the inner layer is reflective to a first wavelength range and not reflective to a second wavelength range.

7. The LED device of claim 5, wherein the second light-altering property of the outer layer is absorptive to a first wavelength range and not absorptive to a second wavelength range.

8. The LED device of claim 1, wherein the LED device comprises a plurality of LED chips disposed on a surface, wherein each LED chip of the plurality of LED chips comprise respective side layers.

9. The LED device of claim 1, wherein the side layer also covers at least a portion of a side of the cover structure.

10. The LED device of claim 1, wherein the inner layer of the side layer is formed from at least one of silicone material or epoxy material.

11. The LED device of claim 1, wherein the outer layer of the side layer is formed from at least one of silicone material or epoxy material.

12. The LED device of claim 1, wherein the cover structure comprises one or more of a lens structure or a layer comprising a lumiphoric material.

13. The LED device of claim 12, wherein the lens structure comprises the lumiphoric material.

14. The LED device of claim 1, wherein the cover structure covers a top surface of the side layer.

15. The LED device of claim 1, wherein the cover structure has a lateral dimension larger than the LED chip, and the side layer bounds both the LED chip and the cover structure.

16. The LED device of claim 1, wherein the cover structure has a lateral dimension smaller than the LED chip, and the side layer bounds both the LED chip and the cover structure.

17. The LED device of claim 1, wherein a top and bottom of the side layer is coplanar with the top face of the LED chip and the bottom face of the LED chip, respectively.

18. The LED device of claim 1, wherein a top and bottom of the side layer is coplanar with a top surface of the cover structure and the bottom face of the LED chip, respectively.

19. The LED device of claim 1, wherein the side layer covers the top face of the LED chip.

20. The LED device of claim 1, wherein the side layer covers a top face of the cover structure.

21. A method comprising:
providing a light-emitting diode (LED) chip;
providing a cover structure over a top surface of the LED chip, the cover structure comprising one or more of a lens layer or a layer comprising a lumiphoric material;
layering a first layer comprising a material with a reflective light-altering property over a top structure and a side of the LED chip;
layering a second layer comprising a material with an absorptive light-altering property over the first layer; and
removing the first layer and the second layer at least from the top of the cover structure, wherein the first layer and the second layer form a side layer bounding at least the top surface and a bottom surface of the LED chip.

22. A method comprising:
providing a light-emitting diode (LED) chip;
providing a cover structure over a top surface of the LED chip, the cover structure comprising one or more of a lens layer or a layer comprising a lumiphoric material;
layering a first layer comprising a material with a reflective light-altering property over a top surface of the cover structure and a side of the LED chip;
removing the first layer at least from the top of the cover structure;
layering a second layer comprising a material with an absorptive light-altering property over a top of the cover structure and the first layer on the side of the LED chip; and
removing the second layer at least from the top of the cover structure, wherein the first layer and the second layer form a side layer bounding at least the top surface and a bottom surface of the LED chip.
